(19) United States
(12) Patent Application Publication
(10) Pub. No.: US 2025/0125385 A1
(43) Pub. Date: Apr. 17, 2025

(54) Fuel Cell Apparatus

(71) Applicants: Hyundai Motor Company, Seoul (KR); Kia Corporation, Seoul (KR)

(72) Inventors: Myung Jin Kim, Suwon-Si (KR); Hee Tae Park, Daegu (KR); Tae Hyun Chun, Yongin-Si (KR); Hye Bin Park, Yongin-Si (KR); Min Gyu Kang, Seoul (KR)

(21) Appl. No.: 18/815,289

(22) Filed: Aug. 26, 2024

(30) Foreign Application Priority Data
Oct. 16, 2023 (KR) 10-2023-0138006

(51) Int. Cl. H01M 8/04007; H02G 3/03; H02G 3/08

(52) U.S. Cl. CPC H01M 8/04067; H02G 3/03; H02G 3/081; H01M 2250/20

(57) ABSTRACT

A fuel cell apparatus includes a fuel cell and a power distribution unit disposed on the fuel cell. The power distribution unit includes a housing, a power component disposed in the housing, a bus bar connected to the power component, and an electrically insulative thermal pad disposed between the bus bar and the housing to transfer heat from the bus bar to the housing.

### CROSS-REFERENCE TO RELATED APPLICATIONS

This application claims the benefit of Korean Patent Application No. 10-2023-0138006, filed on Oct. 16, 2023, which is hereby incorporated by reference as if fully set forth herein.

### TECHNICAL FIELD

The present disclosure relates to a fuel cell apparatus.

### BACKGROUND

A fuel cell apparatus includes a fuel cell and a power distribution unit (e.g., a high-voltage junction box). The power distribution unit may serve to distribute power generated in the fuel cell to high-voltage parts located around the fuel cell.

However, parts included in the power distribution unit, for example, a diode and the like, may emit heat, which may deteriorate the performance of the power distribution unit.

### SUMMARY

The following summary presents a simplified summary of certain features. The summary is not an extensive overview and is not intended to identify key or critical elements.

Systems, apparatuses, and methods are described for a fuel cell apparatus. A fuel cell apparatus may comprise a fuel cell; and a power distribution unit disposed on the fuel cell. The power distribution unit may comprise a housing, a power component disposed in the housing, a bus bar connected to the power component; and a thermal pad, disposed between the bus bar and the housing, configured to transfer heat from the bus bar to the housing, wherein the thermal pad is electrically insulative.

These and other features and advantages are described in greater detail below.

### BRIEF DESCRIPTION OF THE DRAWINGS

The accompanying drawings, which are included to provide a further understanding of the disclosure and are incorporated in and constitute a part of this application, illustrate example(s) of the disclosure and together with the description serve to explain the principle of the disclosure. In the drawings:

FIG. 1 is a perspective view schematically showing a vehicle including a fuel cell apparatus;

FIG. 2A is a plan view of an example of a power distribution unit shown in FIG. 1;

FIG. 2B is a bottom view of the example of the power distribution unit shown in FIG. 2A;

FIG. 3A is a cross-sectional view of a bus bar, a thermal pad, and a housing according to an example;

FIG. 3B is a cross-sectional view of a bus bar, a thermal pad, and a housing according to another example;

FIG. 3C is a cross-sectional view of a bus bar, a thermal pad, and a housing according to still another example;

FIG. 4 is a diagram showing a connection relationship between components included in the power distribution unit;

FIG. 5A is a top perspective view of the power distribution unit according to the example;

FIG. 5B is a plan view of the power distribution unit according to the example;

FIGS. 6A, 6B, 6C, and 6D are views for explaining a first bus bar and a first thermal pad;

FIGS. 7A, 7B, 7C, and 7D are views for explaining a second bus bar and a second thermal pad;

FIGS. 8A, 8B, 8C, and 8D are views for explaining third and fourth bus bars and third and fourth thermal pads;

FIGS. 9A and 9B are perspective views for explaining a fifth bus bar and a fifth thermal pad;

FIG. 10A is a partial perspective view of an area in which the first, second, fourth, and fifth bus bars are disposed;

FIG. 10B is a bottom perspective view of a positive main relay;

FIG. 10C is a partial side view of FIG. 10A;

FIG. 11 is a cross-sectional view of the thermal pad, the bus bar, and the housing; and

FIG. 12 is a graph showing change in temperature in the power distribution unit over time.

### DETAILED DESCRIPTION

The present disclosure will now be described more fully hereinafter with reference to the accompanying drawings, in which various examples are shown. The examples, however, may be embodied in many different forms, and should not be construed as being limited to the examples set forth herein. Rather, these examples are provided so that this disclosure will be more thorough and complete, and will more fully convey the scope of the disclosure to those skilled in the art.

It will be understood that when an element is referred to as being “on” or “under” another element, it may be directly on/under the element, or one or more intervening elements may also be present. When an element is referred to as being “on” or “under”, “under the element” as well as “on the element” may be included based on the element.

In addition, terms, such as “first”, “second”, and the like are used only to distinguish between one subject or element and another subject or element, without necessarily requiring or involving any physical or logical relationship or sequence between the subjects or elements. Relational terms such as “on/upper part/above” and “under/lower part/below” are used to distinguish between one subject or element and another subject or element, and do not require a particular orientation of the relevant subjects or elements.

Hereinafter, a fuel cell apparatus will be described with reference to the accompanying drawings. The fuel cell apparatus will be described using the Cartesian coordinate system (x-axis, y-axis, z-axis) for convenience of description, but may also be described using other coordinate systems. In the Cartesian coordinate system, the x-axis, the y-axis, and the z-axis are perpendicular to each other, but the disclosure are not limited thereto. That is, the x-axis, the y-axis, and the z-axis discussed herein may intersect each other obliquely.

The fuel cell apparatus provided herein substantially obviates one or more problems or disadvantages of the related art. The present disclosure provides a fuel cell apparatus having improved cooling performance. However, the objects to be accomplished by the present disclosure are not limited to the above-mentioned objects, and other objects not mentioned herein will be clearly understood by those skilled in the art from the following description. Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

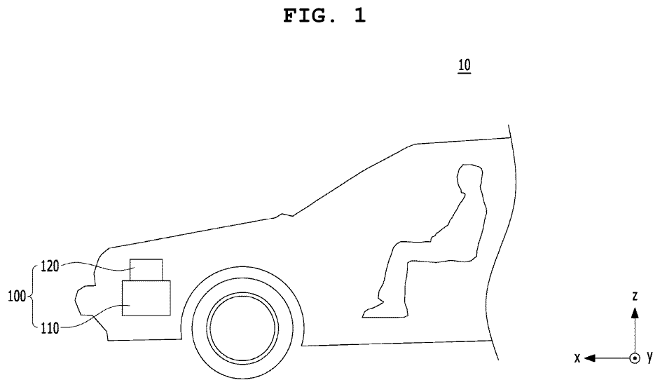

FIG. 1 is a perspective view schematically showing a vehicle 10 including a fuel cell apparatus 100 (hereinafter referred to as a “fuel cell vehicle”).

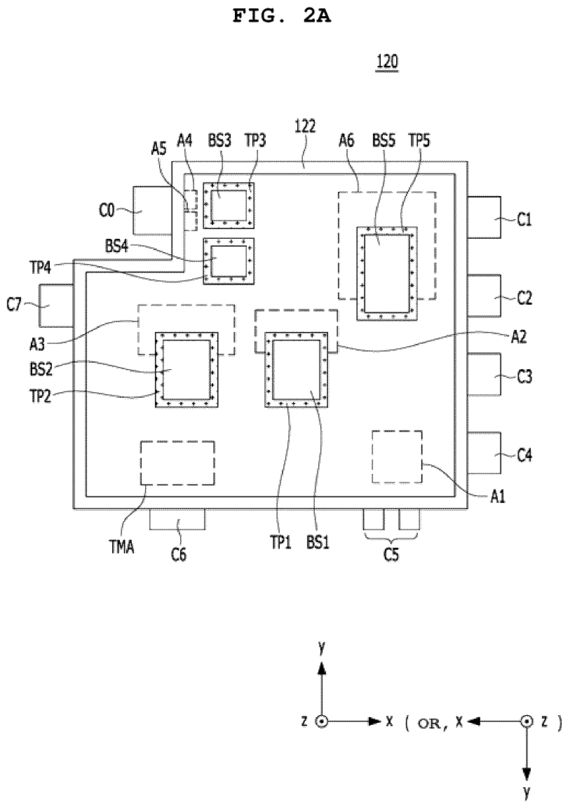

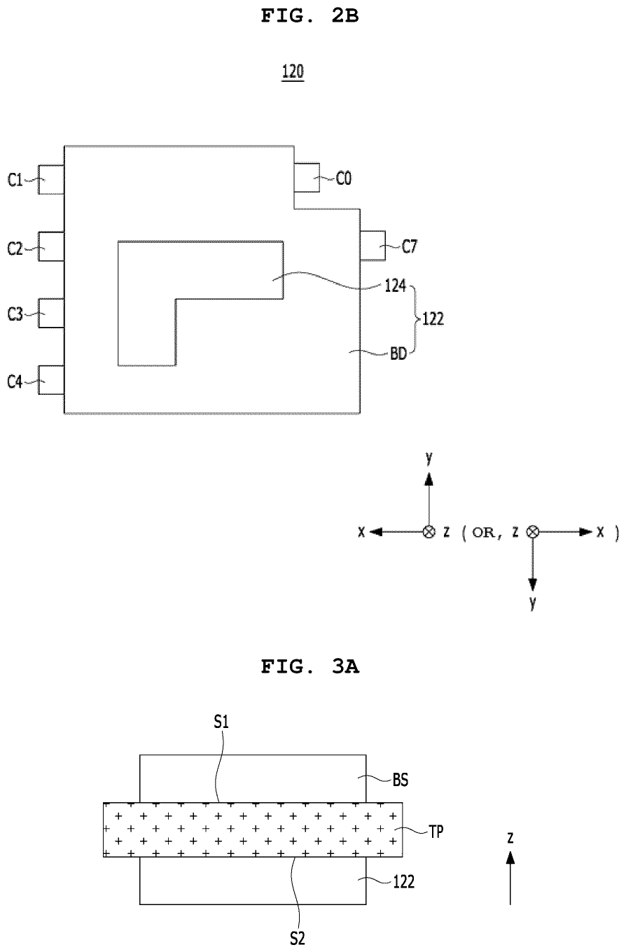

FIG. 2A is a plan view of an example of a power distribution unit (PDU) (a high-voltage junction box or a junction box) 120 shown in FIG. 1, and FIG. 2B is a bottom view of the example of the power distribution unit 120 shown in FIG. 2A.

The fuel cell apparatus 100 according to an example may comprise a fuel cell 110 and a power distribution unit 120.

The fuel cell 110 may be configured to generate power. The fuel cell 110 may be, for example, a polymer electrolyte membrane fuel cell (and/or a proton exchange membrane fuel cell) (PEMFC), or another power source for driving the fuel cell vehicle 10 including the fuel cell apparatus 100. However, the examples are not limited to any specific form of the fuel cell 110 or to the fuel cell 110 or fuel cell vehicles themselves.

The fuel cell 110 may include a cell stack (not shown) and/or a current collector (or a current collecting terminal) (not shown).

The cell stack may include a plurality of unit cells stacked one above another in a first direction (e.g., the x-axis direction), which may be the heading direction (or travel direction) of the fuel cell vehicle 10, or a second direction (e.g., the y-axis direction), which intersects the first direction.

The power distribution unit 120 may be disposed on the fuel cell 110. The power distribution unit 120 may be configured to receive power generated in/by the fuel cell 110 through a terminal block (not shown) and to distribute (e.g., via cables) the power to nearby parts that need the power to operate the fuel cell vehicle 10 (e.g., loads around/connected to the power distribution unit 120 in the fuel cell vehicle 10). To this end, a heater and the current collector in the fuel cell 110 may be connected to the power distribution unit 120. For example, the power distribution unit 120 may be a part that is located at the highest position among the parts disposed in an engine compartment of the fuel cell vehicle 10.

The power distribution unit 120 may include a housing 122, power components, bus bars BS (BS1 to BS5), and thermal pads TP (TP1 to TP5). In FIGS. 2A and 2B, regions of the housing 122 in which the power components may be disposed are exemplarily indicated by dotted lines.

The housing 122 may be configured to accommodate various components of the power distribution unit 120, such as the power components, the bus bars BS, and/or the thermal pads TP.

The bus bars BS may be electrically connected to the power components. The bus bars BS may be configured to transmit power within the power distribution unit 120. Also, or alternatively, the bus bars BS may electrically connect various connectors C1 to C7 to the power components and/or may electrically connect the power components to each other.

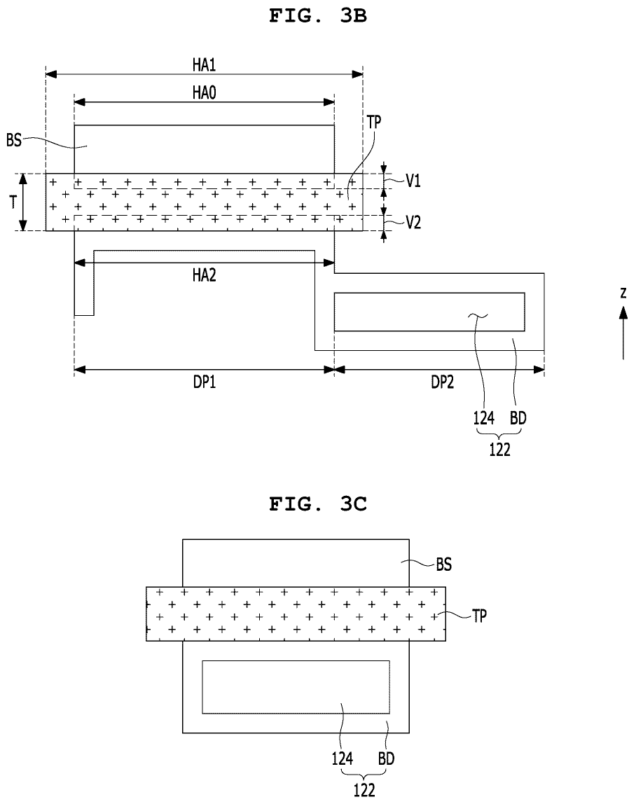

FIG. 3A is a cross-sectional view of a bus bar BS, a thermal pad TP, and a housing 122 according to an example, FIG. 3B is a cross-sectional view of a bus bar BS, a thermal pad TP, and a housing 122 according to another example, and FIG. 3C is a cross-sectional view of a bus bar BS, a thermal pad TP, and a housing 122 according to still another example.

Referring to FIGS. 3A to 3C, the thermal pad TP may be disposed between the bus bar BS and the housing 122 to be configured to transmit heat from the bus bar BS to the housing 122, and may be electrically insulative. According to the illustrated arrangement of the components, heat generated from the power component may be discharged from the bus bar BS to the outside of the power distribution unit 120 through the housing 122 via the thermal pad TP.

Also, or alternatively, the thermal pad TP may be elastic. Therefore, as shown in FIG. 3B, at least a portion of the bus bar BS or the housing 122 may press the thermal pad TP in the z-axis direction, which is a third direction. That is, the bus bar BS, the thermal pad TP, and the housing 122 may overlap each other in the third direction (e.g., z-axis direction), and the thermal pad TP may overlap at least one of the bus bar BS or the housing 122 in the horizontal direction (at least one of the first direction or the second direction), which intersects the third direction.

For example, as shown in FIG. 3B, the thermal pad TP may overlap each of the bus bar BS and the housing 122 in the horizontal direction.

A first thickness V1 by which the thermal pad TP overlaps the bus bar BS in the horizontal direction may be approximately 20% to 40%, e.g., approximately 30%, of the thickness T of the thermal pad TP. For example, the first thickness V1 may be 0.75 mm. Also, or alternatively, a second thickness V2 by which the thermal pad TP overlaps the housing 122 in the horizontal direction may be approximately 20% to 40%, e.g., approximately 30%, of the thickness T of the thermal pad TP. For example, the second thickness V2 may be 0.75 mm.

The housing 122 may include a body BD and a cooling passage 124.

The body BD may define a space configured to accommodates the components of the power distribution unit 120, such as the bus bar BS, the thermal pad TP, and the power component.

The cooling passage 124 may be formed by the body BD and/or may be disposed in the lower side of the housing 122, as shown in FIG. 2B. The cooling passage 124 may be configured to dissipate heat generated in the power distribution unit 120. The cooling passage 124 may be configured to dissipate the heat using a cooling medium, such as air or liquid, flowing in the cooling passage 124. For example, the cooling passage 124 may have a shape such as shown in FIG. 2B when viewed from below, but the disclosure is not limited thereto.

As illustrated in FIG. 3C, in an example, the thermal pad TP may overlap the cooling passage 124 in the third direction, which may be the vertical direction in FIG. 3C, with the body BD interposed therebetween.

As illustrated in FIG. 3B, in an example, the body BD may include first and second portions DP1 and DP2. The first portion DP1 may be defined as a portion that is in direct contact with the thermal pad TP, and the second portion DP2 may be defined as a portion that is adjacent to the first portion DP1 and includes the cooling passage 124 formed therein.

As illustrated in FIG. 3B, the first portion DP1 of the body BD of the housing 122 may have a shape protruding toward the thermal pad TP to contact the thermal pad TP when viewed from a side view.

Also, or alternatively, a first horizontal area HA1 of the thermal pad TP may be larger than a zeroth horizontal area HA0 in which the housing 122, the thermal pad TP, and the bus bar BS overlap each other in the third direction.

Referring to FIG. 3B, the first horizontal area HA1 of the thermal pad TP may be larger than a second horizontal area HA2 of the first portion DP1 protruding from the housing 122. Here, each of the zeroth to second horizontal areas HA0, HA1, and HA2 may be an area of a plane formed by the x-axis and the y-axis. Each of the first and second horizontal areas may be an area of a plane formed by directions intersected with a direction in which the bus bar BS, the thermal pad TP, and the housing 122 are overlap with each other

Also, or alternatively, in the third direction in which the housing 122, the thermal pad TP, and the bus bar BS overlap each other, the thickness T of the thermal pad TP may be large enough to insulate the bus bar BS and the housing 122 from each other, for example, may be 10 mm or more. However, the examples are not limited thereto.

Also, or alternatively, referring to FIG. 3A, the thermal pad TP may include first and second surfaces S1 and S2. The first surface S1 may correspond to a surface contacting the bus bar BS, and/or the second surface S2 may correspond to a surface contacting the housing 122. At least one of the first surface S1 or the second surface S2 may be and/or comprise an adhesive.

Referring to FIG. 2A, the power distribution unit 120 may include a plurality of connectors C0 to C7. For example, the plurality of connectors may include a fuel cell main (FCMAIN) connector C0, a fuel cell air compressor module (FACM) connector C1, a coolant stack pump (CSP) and/or air conditioner compressor (A/CON) (and/or refrigerant compressor) connector C2, a cathode oxygen depletion (COD) heater connector C3, a cooling fan (C/FAN) connector C4, a control connector C5, a cooling connector (or cooling nipple) C6, and/or a battery connector C7.

The FCMAIN connector C0 may be a connector that outputs a voltage required by a motor and/or an inverter (not shown), which is a load. The FCMAIN connector C0 may include a positive main connector PC and a negative main connector NC.

The FACM connector C1 may be a connector that outputs a voltage required by the FACM.

The connector C2 may be a CSP connector that outputs a voltage required by a coolant stack pump (CSP), or the connector C2 may be a A/CON connector that outputs a voltage required by an A/CON. Or, although only one connector C2 is shown in FIG. 2A, the connector C2 may be the multiple connectors where one is connected to the CSP and the other is connected to the A/CON.

The COD heater connector C3 may be a connector that outputs a voltage required by a COD heater (not shown).

The C/FAN connector C4 may be a connector that outputs a voltage required by a cooling fan.

The control connector C5 may be a connector configured to supply power to operate main relays: positive main relay (PR) and negative main relay (NR).

The cooling connector C6 may be a type of port that connects the cooling passage 124 to the outside.

Positive and negative output terminals of the cell stack of the fuel cell, configured to generate power, may be connected to a terminal block area TMA to supply power through the bus bar BS.

The battery connector C7 may be a connector connected to a battery.

The connectors C0 to C7 shown in FIG. 2A are merely illustrative, and the examples are not limited to any specific kinds of connectors or any specific positions at which the connectors are disposed.

Hereinafter, the circuit configuration of the power distribution unit 120 and the position at which the thermal pad TP is disposed according to the example will be described with reference to the accompanying drawings.

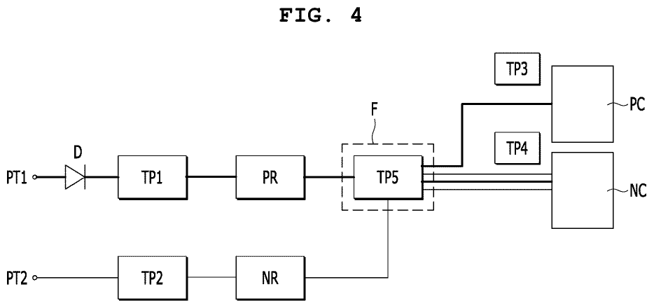

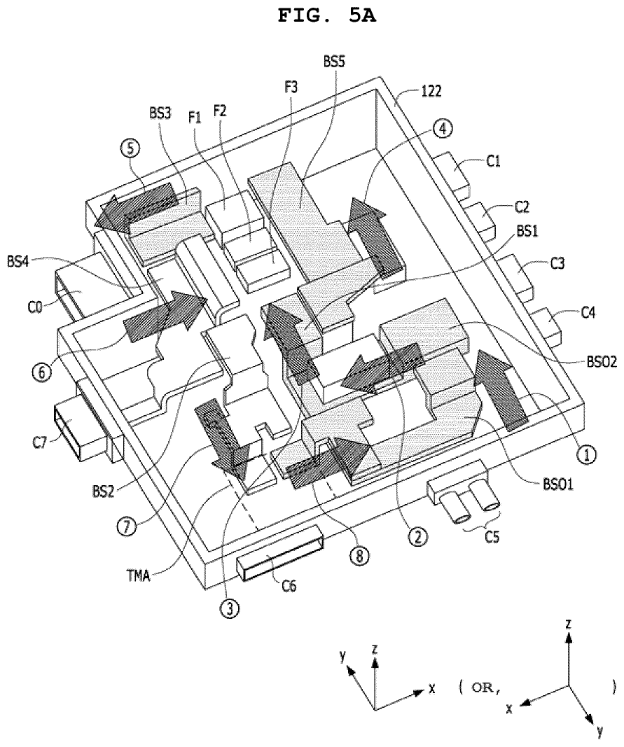

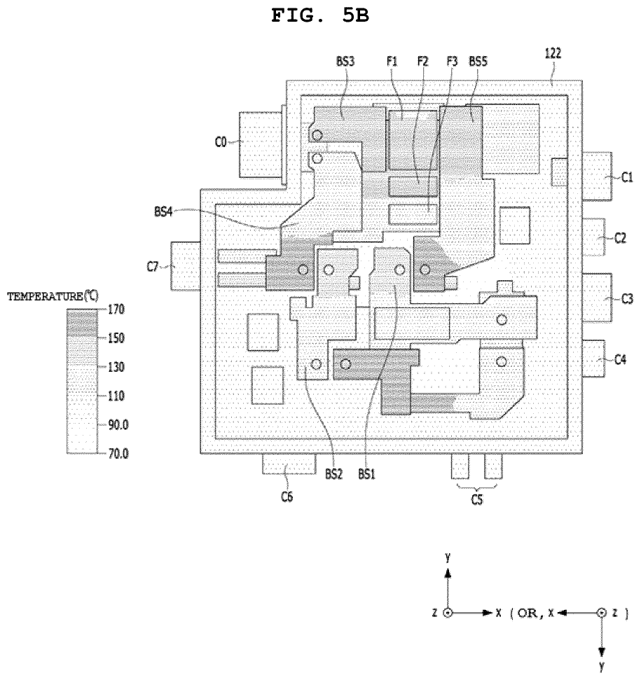

FIG. 4 is a diagram showing a connection relationship between the components included in the power distribution unit 120. For better understanding, the positions of the thermal pads TP are conceptually illustrated, and only parts related to the thermal pads TP are partially illustrated.

The power components may include a positive main relay PR, a negative main relay NR, fuses F1, F2, and F3 (to be described later), and a fuse connector FC. Also, or alternatively, the power components may include wiring or switches (not shown).

For example, the diode D may be disposed in a first area A1 shown in FIG. 2A, and the positive main relay PR, the negative main relay NR, the positive main connector PC, the negative main connector NC, and the fuse connector FC may be disposed in second, third, fourth, fifth, and sixth areas A2, A3, A4, A5, and A6 shown in FIG. 2A, respectively, to be connected to corresponding bus bars BS.

The positive main relay PR and the negative main relay NR may be configured to receive power from the fuel cell through the bus bars BS connected to the terminal block area TMA. That is, the positive main relay PR may be connected to the positive output terminal of the cell stack of the fuel cell by the first bus bar BS1 through a first port PT1 via the diode D, and the negative main relay NR may be connected to the negative output terminal of the cell stack by the second bus bar BS2 through a second port PT2.

The positive main connector PC and the negative main connector NC may be connected to a load through the FCMAIN connector C0.

The fuse connector FC may be connected to a fuse.

Hereinafter, the first to fifth bus bars BS1 to BS5 will be described.

The first bus bar BS1 connects the positive main relay PR to a zeroth bus bar BS02 to be described later, and the second bus bar BS2 connects the negative main relay NR to the terminal block area TMA. Here, the terminal block area TMA connected to the second bus bar BS2 is connected to the negative output terminal of the cell stack.

Also, or alternatively, the third bus bar BS3 connects the positive main connector PC to the fifth bus bar BS5 via the fuse, and the fourth bus bar BS4 connects the negative main connector NC to the fifth bus bar BS5 via the fuse.

The fifth bus bar BS5 is connected to various fuses F.

In this case, the thermal pad TP disposed between each of the first to fifth bus bars BS1 to BS5 and the housing 122, as shown in FIGS. 3A to 3C, may transfer heat from each of the bus bars BS1 to BS5 to the housing 122.

That is, the first thermal pad TP1 may be disposed between the first bus bar BS1 and the housing 122, and/or the second thermal pad TP2 may be disposed between the second bus bar BS2 and the housing 122. Referring to FIG. 4, the first thermal pad TP1 is shown disposed under the first bus bar BS1 connecting the diode D to the positive main relay PR, and the second thermal pad TP2 is shown disposed under the second bus bar BS2 connecting the second port PT2 to the negative main relay NR.

The third thermal pad TP3 may be disposed between the third bus bar BS3 and the housing 122, and/or the fourth thermal pad TP4 may be disposed between the fourth bus bar BS4 and the housing 122. Referring to FIG. 4, the third thermal pad TP3 is shown disposed under the third bus bar BS3 connecting the fuse F to the positive main connector PC, and the fourth thermal pad TP4 is shown disposed under the fourth bus bar BS4 connecting the fuse F to the negative main connector NC.

The fifth thermal pad TP5 may be disposed between the fifth bus bar BS5 and the housing 122. The fifth thermal pad TP5 may be disposed under the fifth bus bar BS5 connecting the positive main relay PR to the third bus bar BS3 via the fuse F.

Hereinafter, an example of the power distribution unit 120 according to the above-described example will be described with reference to the accompanying drawings. However, the examples are not limited thereto. In FIGS. 5A to 11, the same components as those shown in FIGS. 1 to 4 are denoted by the same reference numerals, and a duplicate description thereof will be omitted.

FIG. 5A is a top perspective view of the power distribution unit according to the example, and FIG. 5B is a plan view of the power distribution unit according to the example. In FIG. 5A, a direction in which current flows is indicated by arrows.

The power distribution unit shown in FIG. 5A may comprise the above-described first to fifth bus bars BS1 to BS5 and connectors C0 to C7. Also, or alternatively, the power distribution unit may further include zeroth bus bars BS01 and BS02 disposed in the first area A1. One (e.g., BS01) of the zeroth bus bars may be connected to a positive electrode of the diode D and the terminal block area TMA, and the other (e.g., BS02) of the zeroth bus bars may be connected to a negative electrode of the diode D and the first bus bar BS1.

A path along which current flows within the power distribution unit will be described below with reference to FIG. 5A.

Current flows to the positive main relay PR ( [symbol] ) via the zeroth bus bars BS01 and BS02 connected to the diode D ( [symbol] ) through the terminal block area TMA ( [symbol] ). Subsequently, the current flows from the positive main relay PR ( [symbol] ) to the positive main connector PC through the third bus bar BS3 ( [symbol] ) via the fifth bus bar BS5 ( [symbol] ). Subsequently, the current flows to the negative main relay NR ( [symbol] ) from the negative main connector NC connected to a negative terminal of a load through the FCMAIN connector C0 ( [symbol] ), and then flows to the terminal block area TMA.

The above-described path along which the current flows is only an example. The examples are not limited to any specific current flow path. As described above, the power components are electrically connected to each other through the bus bars BS in order to form the current flow path.

Hereinafter, an area in which the thermal pad TP is disposed will be described in more detail with reference to the accompanying drawings.

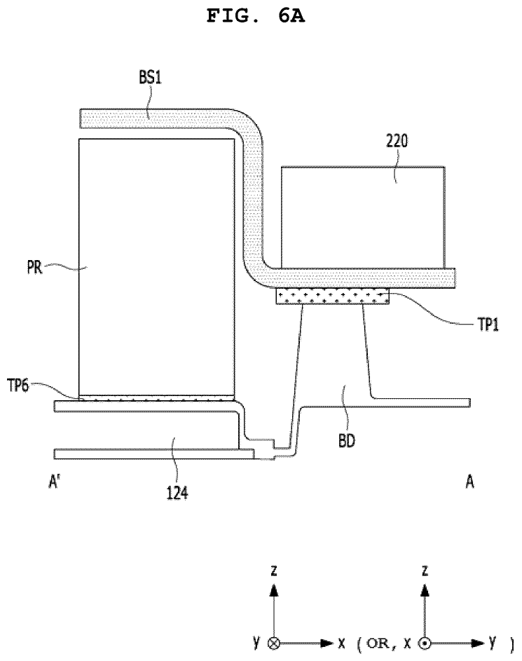

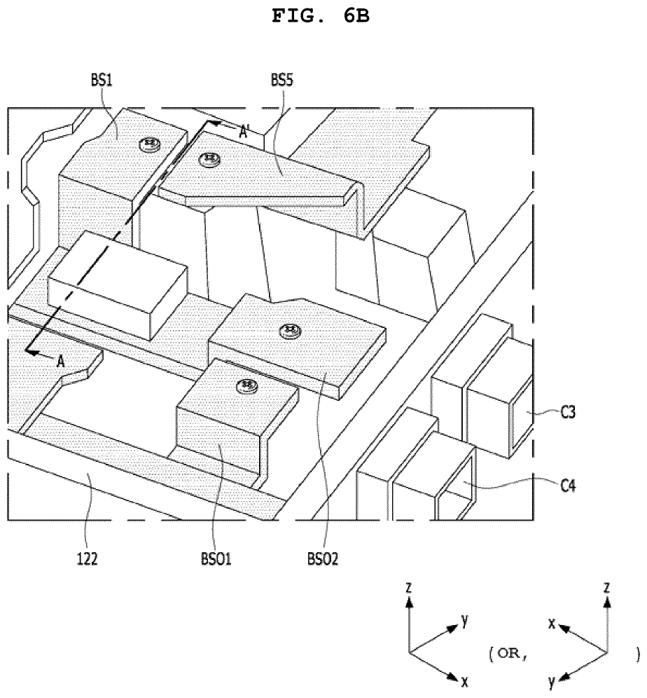

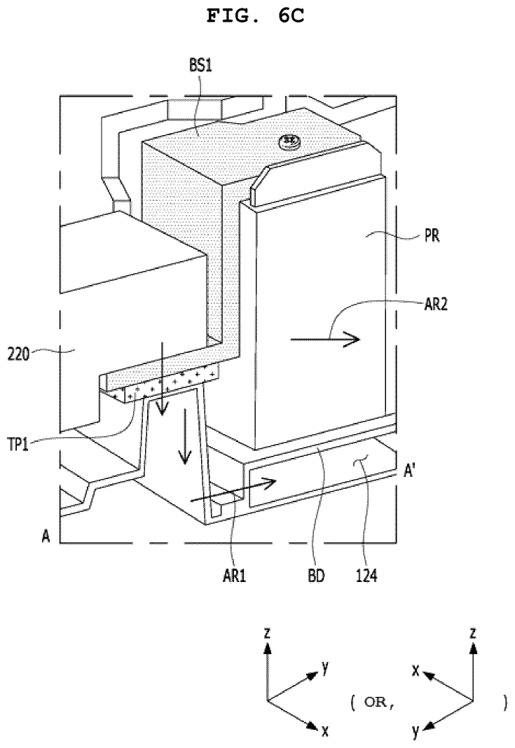

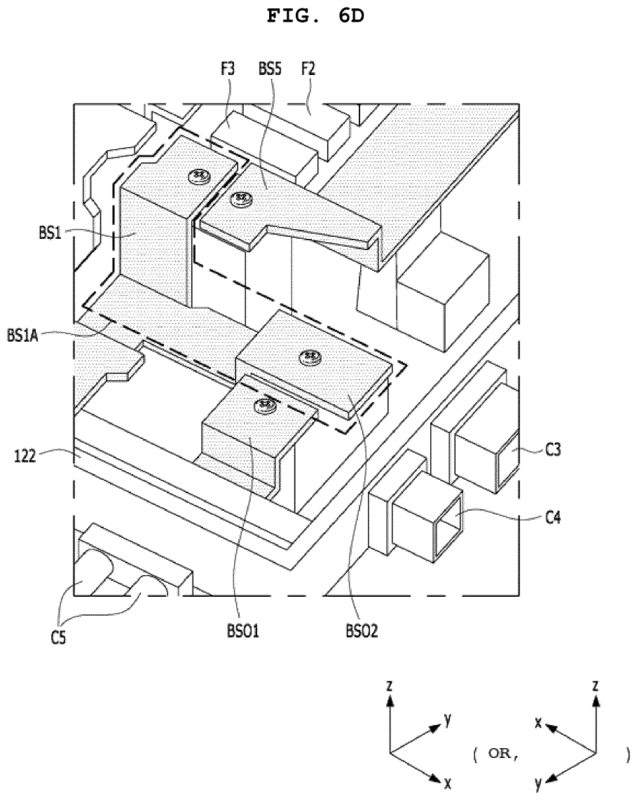

FIGS. 6A to 6D are views for explaining the first bus bar BS1 and the first thermal pad TP1. FIGS. 6A and 6C are cross-sectional views taken along line A-A′ shown in FIG. 6B, and FIG. 6D is a partial cross-sectional view of the power distribution unit shown in FIG. 5A, with a fuse case 220 removed therefrom.

The power distribution unit may further include a fuse case 220, which may be disposed on the first bus bar BS1 and/or may accommodate various fuses. Referring to FIG. 6D, the fuse case 220 may be disposed in an area BS1A on the first bus bar BS1.

Referring to FIGS. 6A to 6D, it can be seen that the first thermal pad TP1 is disposed between the first bus bar BS1 and the housing 122. In this case, as shown in FIG. 6A, the cooling passage 124 may be disposed in the second portion DP2 shown in FIG. 3B. However, the examples are not limited thereto. The cooling passage 124 may also, or alternatively, be disposed as shown in FIG. 3C.

As illustrated, since the fuse case 220 is disposed on the first bus bar BS1, heat may not escape to the upper structure, but may escape in the direction indicated by the arrow AR1 through the first thermal pad TP1. The heat may also, or alternatively, escape in the direction indicated by the arrow AR2.

As shown in FIG. 6A, in an example, a sixth thermal pad TP6 may be further disposed between the positive main relay PR and the cooling passage 124. Therefore, heat generated from the positive main relay PR may escape via the housing 122 through the sixth thermal pad TP6. Since the cooling passage 124 of the housing 122 overlaps the sixth thermal pad TP6 in the vertical direction, heat may escape more quickly.

The sixth thermal pad TP6 may be different only in placement position from the first to fifth thermal pads TP1 to TP5. The sixth thermal pad TP6 may have the same characteristics as the first to fifth thermal pads TP1 to TP5, and thus a duplicate description thereof will be omitted.

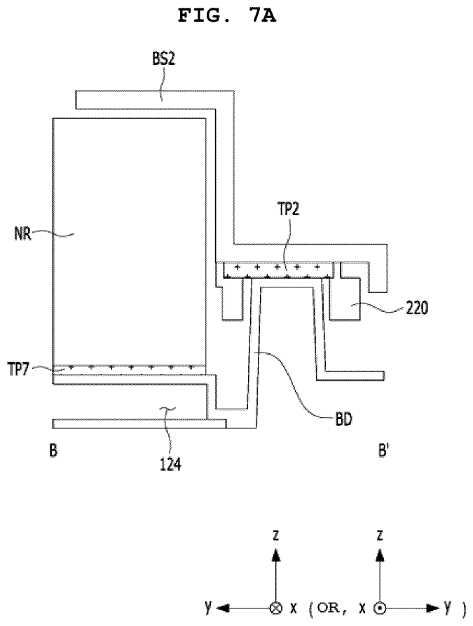

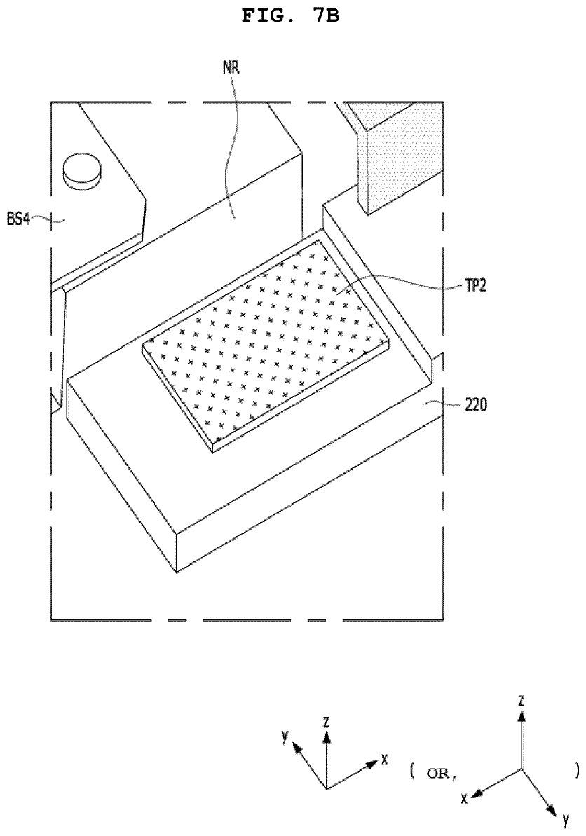

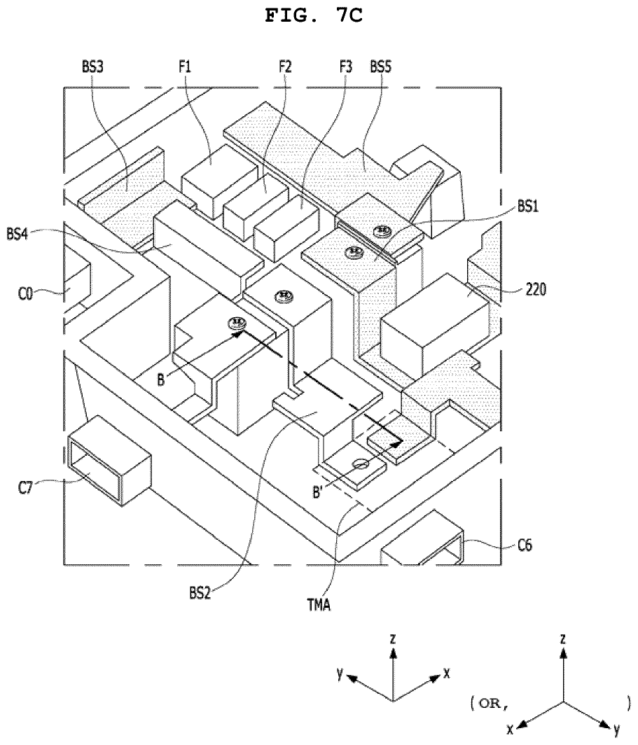

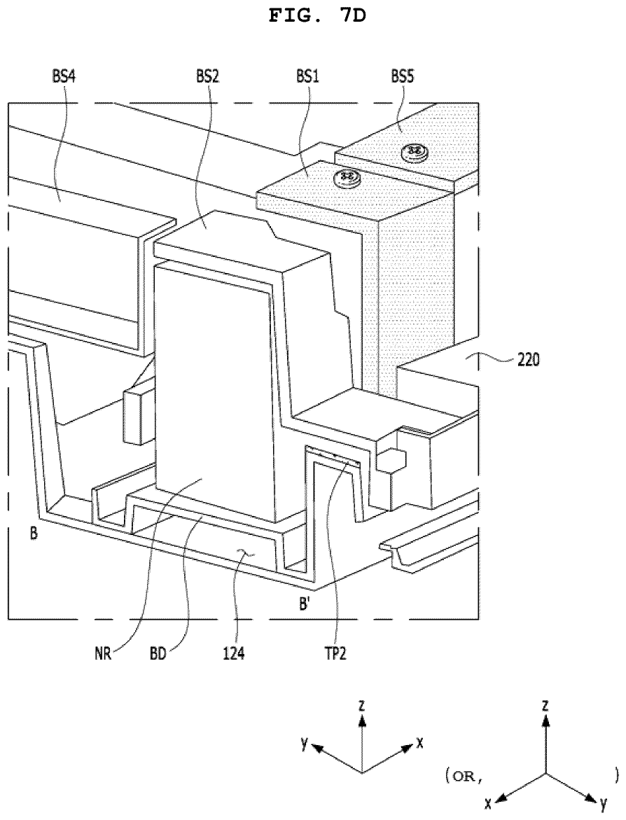

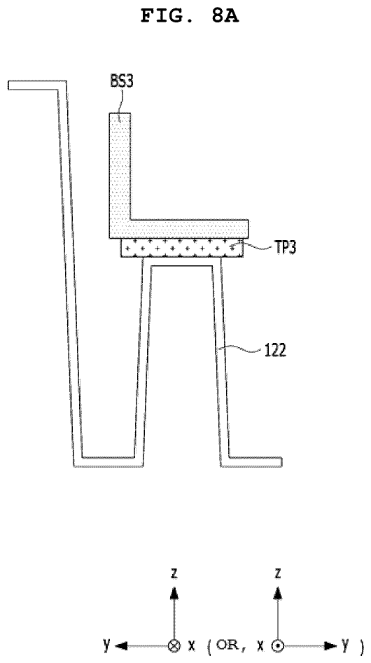

FIGS. 7A to 7D are views for explaining the second bus bar BS2 and the second thermal pad TP2. FIGS. 7A and 7D are cross-sectional views taken along line B-B′ shown in FIG. 7C, FIG. 7B is a partial perspective view of FIG. 7A, with the second bus bar BS2 removed therefrom, and FIG. 7C is a partial cross-sectional view of the power distribution unit 120 shown in FIG. 5.

Referring to FIGS. 7A to 7D, the second bus bar BS2 may connect the negative main relay NR to the terminal block area TMA. In this case, as illustrated, the second thermal pad TP2 may be disposed between the second bus bar BS2 and the housing 122. As shown in FIG. 7A, for example, the cooling passage 124 may be disposed in the second portion DP2 shown in FIG. 3B. However, the examples are not limited thereto. The cooling passage 124 may also, or alternatively, be disposed as shown in FIG. 3C.

As illustrated, heat from the second bus bar BS2 may escape to the outside via the housing 122 through the second thermal pad TP2. Referring to FIGS. 7A and 7B, it can be seen that a portion of the fuse case 220 is cut to place the second thermal pad TP2.

As shown in FIG. 7A, in an example, a seventh thermal pad TP7 may be further disposed between the negative main relay NR and the cooling passage 124. Therefore, heat generated from the negative main relay NR may escape via the housing 122 through the seventh thermal pad TP7. Since the cooling passage 124 of the housing 122 overlaps the seventh thermal pad TP7 in the vertical direction, heat may escape more quickly.

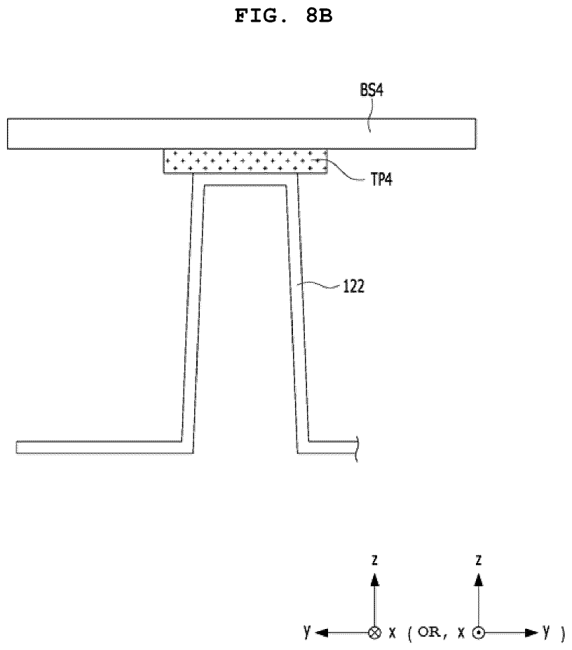

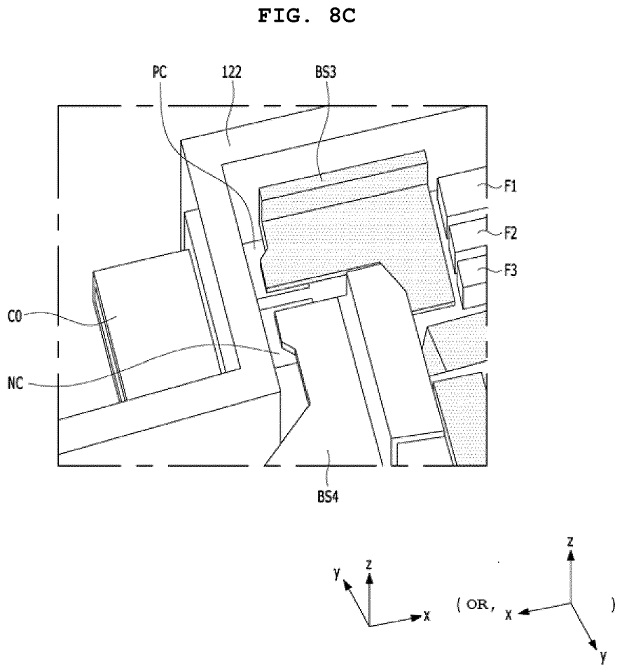

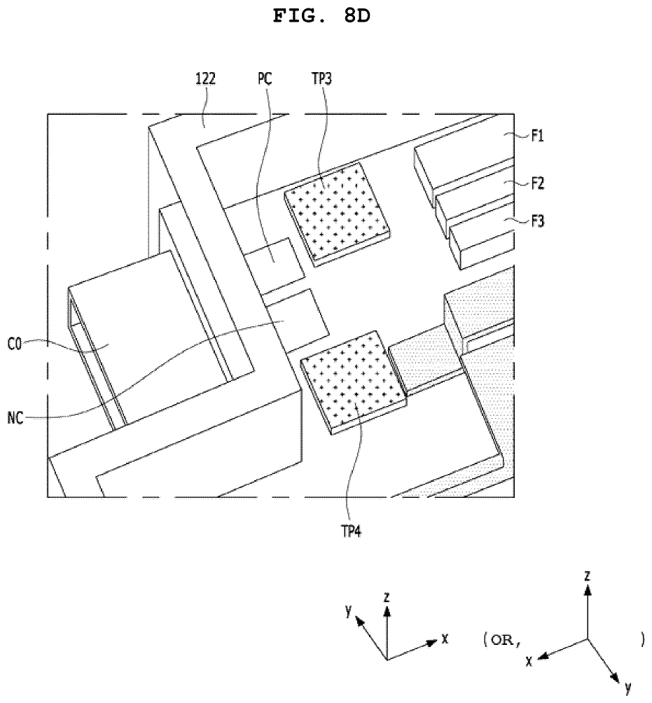

FIGS. 8A to 8D are views for explaining the third and fourth bus bars BS3 and BS4 and the third and fourth thermal pads TP3 and TP4. FIG. 8A is a cross-sectional view of the third bus bar BS3 and the third thermal pad TP3, FIG. 8B is a cross-sectional view of the fourth bus bar BS4 and the fourth thermal pad TP4, FIG. 8C is a top perspective view of the third and fourth bus bars BS3 and BS4, and FIG. 8D is a top perspective view, with the third and fourth bus bars BS3 and BS3 removed from FIG. 8C.

Referring to FIGS. 8A to 8D, the third bus bar BS3 may connect the first fuse F1 connected to the fifth bus bar BS5 to the positive main connector PC. Heat from the third bus bar BS3 may be dissipated to the outside through the third thermal pad TP3 disposed between the third bus bar BS3 and the housing 122. The fourth bus bar BS4 may connect the second and third fuses, F2 and F3, to the negative main connector NC. Heat from the fourth bus bar BS4 may be dissipated to the outside through the fourth thermal pad TP4 disposed between the fourth bus bar BS4 and the housing 122.

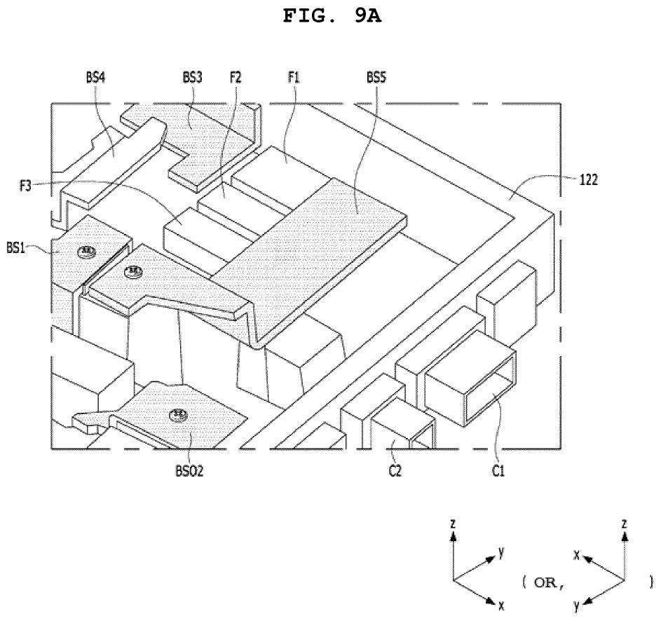

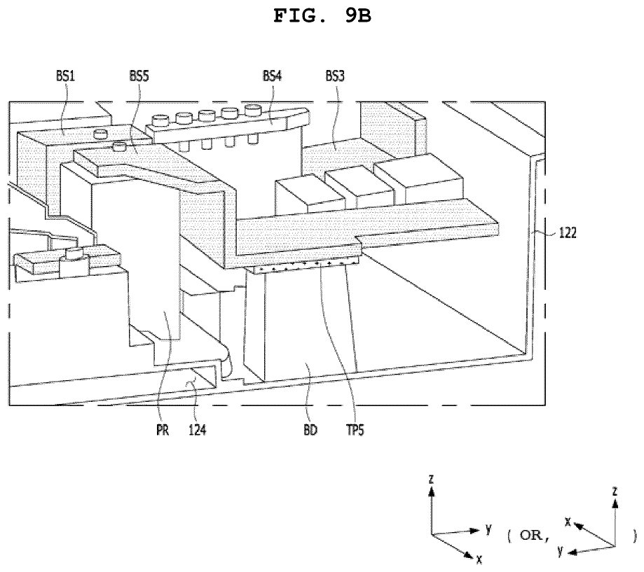

FIGS. 9A and 9B are perspective views for explaining the fifth bus bar BS5 and the fifth thermal pad TP5.

Referring to FIGS. 9A and 9B, the fifth bus bar BS5 connects the positive main relay PR to various fuses (e.g., F1, F2, and F3), and heat from the fifth bus bar BS5 may be dissipated to the outside through the fifth thermal pad TP5 disposed between the fifth bus bar BS5 and the housing 122.

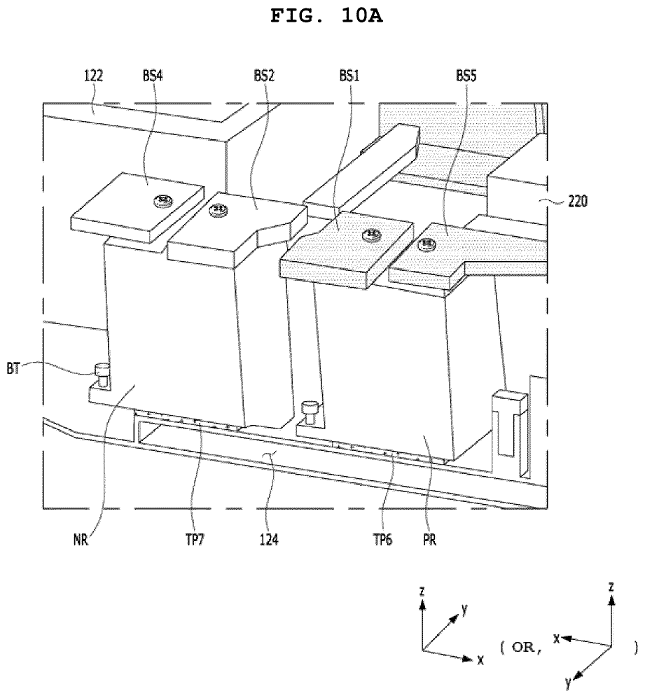

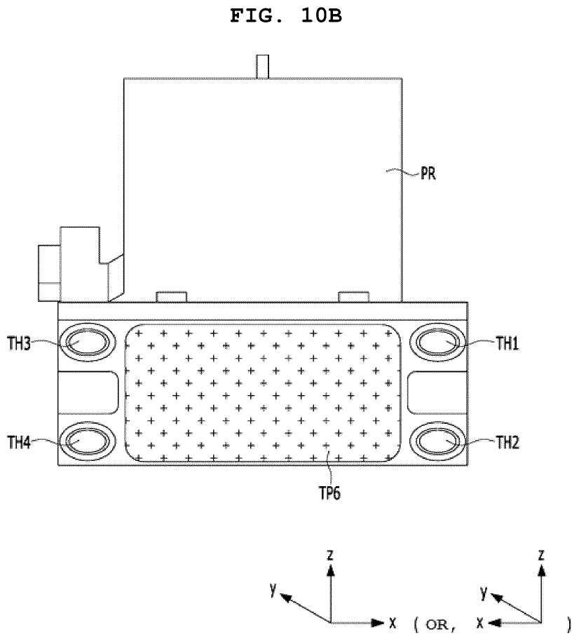

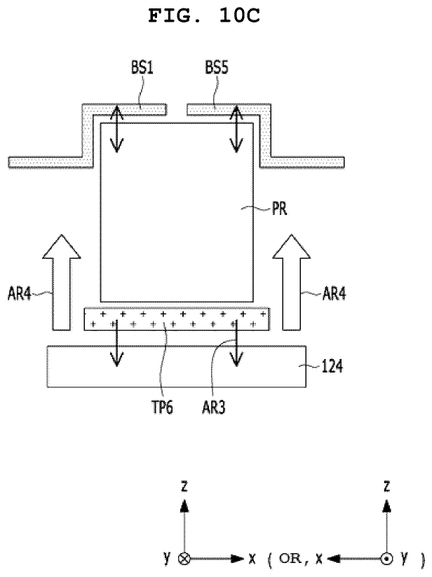

FIG. 10A is a partial perspective view of an area in which the first, second, fourth, and fifth bus bars BS1, BS2, BS4, and BS5 are disposed, FIG. 10B is a bottom perspective view of the positive main relay PR, and FIG. 10C is a partial side view of FIG. 10A.

As described above, each of the sixth and seventh thermal pads TP6 and TP7 may be thermally conductive and electrically insulative. Therefore, as shown in FIG. 10C, the sixth thermal pad TP6 may dissipates heat from the positive relay PR to the cooling passage 124 of the housing 122 in a third arrow direction AR3.

Also, or alternatively, if the fuel cell apparatus 100 according to the example is mounted in the fuel cell vehicle 10, e.g. as shown in FIG. 1, if the sixth thermal pad TP6 is elastic, the sixth thermal pad TP6 may absorb vibration of the vehicle 10 transferred in a fourth arrow direction AR4, as shown in FIG. 10C. The seventh thermal pad TP7 may also play the same role(s) as the sixth thermal pad TP6.

Each of the sixth and seventh thermal pads TP6 and TP7 may be disposed adjacent to bolts BT that fix the power components to the housing 122. For example, as shown in FIG. 10B, the sixth thermal pad TP6 may be disposed adjacent to through-holes TH1 to TH4 through which the bolts BT pass to fix the positive main relay PR to the housing 122. Parts to which the bolts BT are fastened may be most influenced by vibration of the fuel cell vehicle 10. In consideration thereof, the sixth and seventh thermal pads TP6 and TP7, which may be elastic, may be disposed close to the parts to which the bolts BT are fastened in order to more effectively absorb vibration of the fuel cell vehicle 10 in the vertical direction.

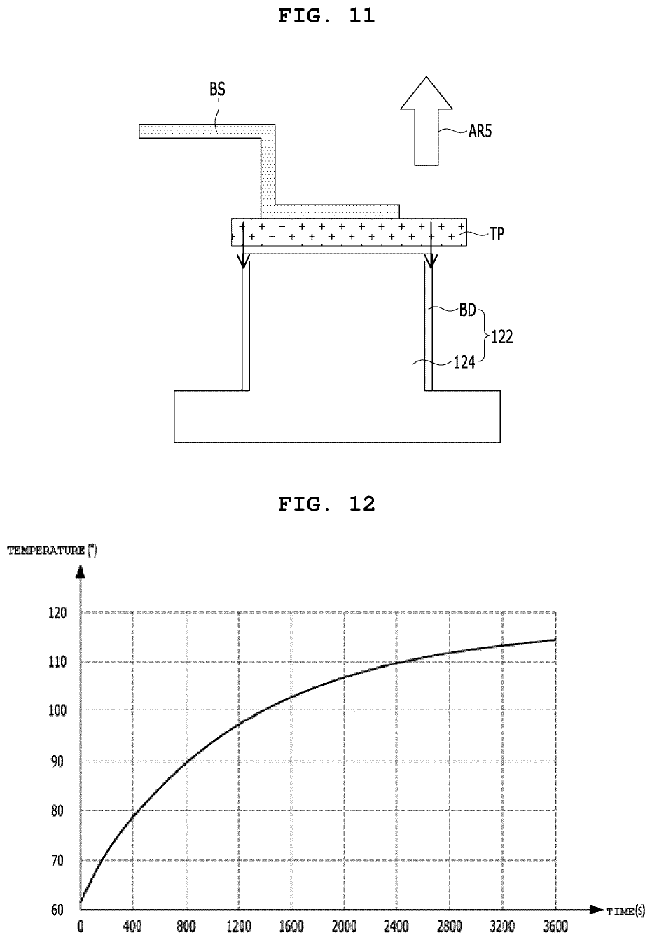

FIG. 11 is a cross-sectional view of the thermal pad TP, the bus bar BS, and the housing 122.

The thermal pad TP shown in FIG. 11 may correspond to one of the first to fifth thermal pads TP1 to TP5, and the bus bar BS may correspond to one of the first to fifth bus bars BS1 to BS5.

Also, or alternatively, if the fuel cell apparatus 100 is mounted in the fuel cell vehicle 10 (e.g., as shown in FIG. 1), if the thermal pad TP is elastic, the thermal pad TP may absorb vibration of the fuel cell vehicle 10 transferred in a fifth arrow direction AR5, as shown in FIG. 11.

Hereinafter, the effect of the fuel cell apparatus will be described.

As illustrated in FIG. 3B, in an example, since the thermal pad TP overlaps at least one of the bus bar BS or the housing 122 in the horizontal direction (e.g., at least one of the x-axis direction or the y-axis direction), the heat transfer efficiency of the thermal pad TP may be maximized.

As illustrated in FIG. 3B, the zeroth to second horizontal areas HA0, HA1, and HA2 and thickness T may be determined in consideration of a sufficient insulation distance and electrical disconnection between the bus bar BS and the housing 122. That is, when the first horizontal area HA1 is larger than the zeroth and second horizontal areas HA0 and HA2 and the thickness T is sufficiently large, a sufficient insulation distance and electrical disconnection may be secured between the bus bar BS and the housing 122. Accordingly, electrical stability may be ensured.

As illustrated in FIG. 3B, if the body BD of the housing 122 protrudes toward the thermal pad TP and is in direct contact with the thermal pad TP, efficiency of heat transfer between the thermal pad TP and the housing 122 may increase, and thus heat may be dissipated more quickly to the outside through the housing 122.

FIG. 12 is a graph showing change in temperature in the power distribution unit 120 over time. The vertical axis of the graph represents temperature, and the horizontal axis thereof represents time.

Referring to FIG. 12, it can be seen that the temperature in the power distribution unit 120 increases over time. That is, as shown in FIG. 5A, since current flows within the power distribution unit 120, heat may be generated within an allowable operation range depending on the output condition/operating environment of the fuel cell vehicle 10. Among the components included in the power distribution unit 120, the bus bars BS, the main relays PR and NR, and the fuses are main heat sources. Depending on the direction in which the current flows, the temperature tends to gradually increase as shown in FIG. 12. In some cases, if the temperature exceeds an allowable temperature limit of a component, it is necessary to cool the component. However, if the conventional air-cooling method or water-cooling method is used to cool heat-generating components of the power distribution unit 120, a heat-generating component that is not located on the path along which a cooling fluid flows within the power distribution unit 120 may not be properly cooled, and thus may be damaged or shortened in lifespan.

In contrast, according to the example, the thermal pad TP is disposed under the bus bar BS of a main heat source within the power distribution unit 120, thereby dissipating heat to the outside through the housing 122.

Also, or alternatively, since the cooling passage 124 of the housing 122 is disposed under the thermal pad TP, a heat dissipation effect thereof may be maximized.

For example, local heat-generating areas in the power distribution unit 120 may be confirmed in advance through heat distribution analysis and temperature rise analysis using the data shown in FIG. 5B, and the thermal pads TP may be disposed in the corresponding areas, whereby the temperature of the local heat-generating areas in the power distribution unit 120 may be effectively lowered, and thus thermal damage to components (e.g., abnormal operation of components due to fusion or melting) may be prevented. Accordingly, the lifespan of the power distribution unit 120 may be prolonged, and performance reduction thereof due to degradation of components may be prevented. As such, since damage to components of the power distribution unit 120 is minimized, it may be possible to protect the cell stack and parts in an engine compartment of the vehicle. Furthermore, it may be possible to protect a user of the fuel cell apparatus or a surrounding environment of the user.

A fuel cell apparatus may include a fuel cell and a power distribution unit disposed on the fuel cell, wherein the power distribution unit may include a housing, a power component disposed in the housing, a bus bar connected to the power component, and an electrically insulative thermal pad disposed between the bus bar and the housing to transfer heat from the bus bar to the housing.

In an example, the thermal pad may be elastic.

In an example, the bus bar, the thermal pad, and the housing may overlap each other in a first direction, and the thermal pad may overlap at least one of the bus bar or the housing in a direction intersecting the first direction.

In an example, the housing may include a body defining a space accommodating the power component and a cooling passage disposed in a lower side of the housing.

In an example, the thermal pad may overlap the cooling passage in a vertical direction, with the body interposed therebetween.

In an example, the body may include a first portion contacting the thermal pad and a second portion formed to be adjacent to the first portion and including the cooling passage formed therein.

In an example, the housing may have a shape protruding toward the thermal pad to contact the thermal pad when viewed from a side view.

In an example, the horizontal area of the thermal pad may be larger than the horizontal area of a portion protruding from the housing.

In an example, the thermal pad may have a thickness of 10 mm or more in a direction in which the housing, the thermal pad, and the bus bar overlap each other.

In an example, the horizontal area of the thermal pad may be larger than a horizontal area in which the housing, the thermal pad, and the bus bar overlap each other in the first direction.

In an example, the thermal pad may include a first surface contacting the bus bar and a second surface contacting the housing, and at least one of the first surface or the second surface may be adhesive.

In an example, the power component may include a positive main relay and a negative main relay configured to receive power from the fuel cell. The bus bar may include a first bus bar connected to the positive main relay and a second bus bar connected to the negative main relay, and the thermal pad may include a first thermal pad disposed between the first bus bar and the housing and a second thermal pad disposed between the second bus bar and the housing.

In an example, the fuel cell apparatus may further include a fuse case disposed on the first bus bar to accommodate a fuse.

In an example, the bus bar may include a third bus bar connected to a positive main connector connected to a load and a fourth bus bar connected to a negative main connector connected to the load, and the thermal pad may include a third thermal pad disposed between the third bus bar and the housing and a fourth thermal pad disposed between the fourth bus bar and the housing.

In an example, the bus bar may include a fifth bus bar connected to a fuse, and the thermal pad may include a fifth thermal pad disposed between the fifth bus bar and the housing.

It is to be understood that both the foregoing general description and the following detailed description of the present disclosure are exemplary and explanatory and are intended to provide further explanation of the disclosure as claimed.

The fuel cell apparatus according to the above-described example may be applied to vehicles, aircraft, ships, stationary power generation systems, and the like, without being limited thereto.

As is apparent from the above description, the fuel cell apparatus according to the example may quickly dissipate heat from a power distribution unit to the outside, thereby increasing the lifespan of the power distribution unit, preventing performance reduction thereof due to degradation of components, and protecting a cell stack and parts in an engine compartment of a vehicle. Furthermore, it may be possible to protect a user of the fuel cell apparatus or a surrounding environment of the user and to absorb small vibration of the vehicle.

However, the effects achievable through the disclosure are not limited to the above-mentioned effects, and other effects not mentioned herein will be clearly understood by those skilled in the art from the above description.

The above-described various examples may be combined with each other without departing from the scope of the present disclosure unless they are incompatible with each other.

Also, or alternatively, for any element or process that is not described in detail in any of the various examples, reference may be made to the description of an element or a process having the same reference numeral in another example, unless otherwise specified.

While the present disclosure has been particularly shown and described with reference to examples thereof, these examples are only proposed for illustrative purposes, and do not restrict the present disclosure, and it will be apparent to those skilled in the art that various changes in form and detail may be made without departing from the essential characteristics of the examples set forth herein. For example, respective configurations set forth in the examples may be modified and applied. Further, differences in such modifications and applications should be construed as falling within the scope of the present disclosure as defined by the appended claims.

What is claimed is:

1. A fuel cell apparatus, comprising:
a fuel cell; and
a power distribution unit disposed on the fuel cell,
wherein the power distribution unit comprises:
a housing;
a power component disposed in the housing;
a bus bar connected to the power component; and
a thermal pad, disposed between the bus bar and the housing, configured to transfer heat from the bus bar to the housing, wherein the thermal pad is electrically insulative.

2. The fuel cell apparatus according to claim 1, wherein the thermal pad is elastic.

3. The fuel cell apparatus according to claim 1, wherein the bus bar, the thermal pad, and the housing overlap each other in a first direction, and
wherein the thermal pad overlaps at least one of the bus bar or the housing in a direction intersecting the first direction.

4. The fuel cell apparatus according to claim 1, wherein the housing comprises:
a body defining a space configured to accommodate the power component; and
a cooling passage disposed in a side of the housing.

5. The fuel cell apparatus according to claim 4, wherein the thermal pad overlaps the cooling passage in a vertical direction, with the body interposed therebetween.

6. The fuel cell apparatus according to claim 4, wherein the body comprises:
a first portion in contact with the thermal pad; and
a second portion disposed to be adjacent to the first portion and comprising the cooling passage disposed therein.

7. The fuel cell apparatus according to claim 1, wherein the housing comprises a protrusion in contact with the thermal pad.

8. The fuel cell apparatus according to claim 7, wherein a first horizontal area of the thermal pad is larger than a second horizontal area of the protrusion of the housing, and
wherein each of the first and second horizontal areas is an area of a plane formed by directions intersected with a direction in which the bus bar, the thermal pad, and the housing overlap each other.

9. The fuel cell apparatus according to claim 1, wherein the thermal pad has a thickness of 10 mm or more in a direction in which the housing, the thermal pad, and the bus bar overlap each other.

10. The fuel cell apparatus according to claim 1, wherein the housing, the thermal pad, and the bus bar overlap each other in a first direction, and wherein an area of the thermal pad in a plane perpendicular to the first direction is larger than an area over which the housing, the thermal pad, and the bus bar overlap each other.

11. The fuel cell apparatus according to claim 1, wherein the thermal pad comprises:
a first surface in contact with the bus bar; and
a second surface in contact with the housing,
wherein at least one of the first surface or the second surface is adhesive.

12. The fuel cell apparatus according to claim 1, wherein the power component comprises a positive main relay and a negative main relay configured to receive power from the fuel cell, wherein the bus bar comprises:
a first bus bar connected to the positive main relay; and
a second bus bar connected to the negative main relay, and
wherein the thermal pad comprises:
a first thermal pad disposed between the first bus bar and the housing; and
a second thermal pad disposed between the second bus bar and the housing.

13. The fuel cell apparatus according to claim 12, further comprising a fuse case disposed on the first bus bar so as to be configured to accommodate a fuse.

14. The fuel cell apparatus according to claim 1, wherein the bus bar comprises:
a third bus bar connected to a positive main connector connected to a load; and
a fourth bus bar connected to a negative main connector connected to the load, and
wherein the thermal pad comprises:
a third thermal pad disposed between the third bus bar and the housing; and
a fourth thermal pad disposed between the fourth bus bar and the housing.

15. The fuel cell apparatus according to claim 1, wherein the bus bar comprises a fifth bus bar connected to a fuse, and
wherein the thermal pad comprises a fifth thermal pad disposed between the fifth bus bar and the housing.
